(19) United States
(12) Patent Application Publication
(10) Pub. No.: US 2003/0038305 A1
(43) Pub. Date: Feb. 27, 2003

(54) Method for manufacturing and structure of transistor with low-k spacer

(76) Inventor: Christoph A. Wasshuber, Parker, TX (US)

Correspondence Address: TEXAS INSTRUMENTS INCORPORATED, P O BOX 655474, M/S 3999, DALLAS, TX, 75265

(21) Appl. No.: 10/214,667

(22) Filed: Aug. 8, 2002

Related U.S. Application Data
(60) Provisional application No. 60/314,106, filed on Aug. 21, 2001.

(51) Int. Cl. H01L 29/76

(52) U.S. Cl. 257/213

(57) ABSTRACT

A method for manufacturing a transistor includes forming a gate dielectric layer adjacent a semiconductor substrate. A gate electrode may be formed covering at least a portion of the gate dielectric layer. First and second doped regions of the semiconductor substrate may be formed proximate the gate electrode and separated by a channel region. First and second spacers may be formed at least partially in contact with the gate electrode. The first and second spacers may each comprise a material having a dielectric coefficient value less than the dielectric coefficient value of silicon dioxide. Third and fourth doped regions of the semiconductor substrate may be formed proximate the first and second spacers, respectively.

### BACKGROUND OF THE INVENTION

The demand for semiconductor devices to be made smaller is ever present because size reduction typically increases speed and decreases power consumption. As semiconductor devices become smaller, there is a need to decrease the size of transistors used for semiconductor devices.

A typical transistor generally includes a gate electrode formed near a semiconductor substrate to control the flow of current from a source to a drain of the transistor and metal contacts which facilitate the flow of electrical current to and from source and drain regions of the transistor. Sidewall spacers formed proximate the gate electrode are used as implant blockers and as well as to prevent the components of the transistor from shorting during various stages of the manufacturing process of the transistor. The sidewall spacers create an undesired capacitance between the metal contacts and the gate electrode. Furthermore, as the components of the transistor decrease in size, this capacitance between the gate electrode and the contacts gets larger. This gate-to-contact capacitance constitutes approximately ten to fifteen percent of the overall capacitance of the transistor (or the capacitance between the gate electrode and the drain or between the gate electrode and the source). The higher the overall capacitance, the greater the adverse effect on the operation of the transistor. For example, the higher the overall capacitance, the slower the switching speed of the transistor.

### SUMMARY OF THE INVENTION

The present invention provides a transistor and method for manufacturing the same that substantially eliminates or reduces at least some of the disadvantages and problems associated with previously developed transistors and methods for manufacturing the same.

In accordance with a particular embodiment of the present invention, a method for manufacturing a semiconductor is provided. The method includes forming a gate dielectric layer adjacent a semiconductor substrate. A gate electrode is formed covering at least a portion of the gate dielectric layer. First and second doped regions of the semiconductor substrate are formed proximate the gate electrode and are separated by a channel region. The method further includes forming first and second spacers at least partially in contact with the gate electrode. The first and second spacers each comprise a material having a dielectric coefficient value less than the dielectric coefficient value of silicon dioxide. Third and fourth doped regions of the semiconductor substrate are formed proximate the first and second spacers, respectively.

In accordance with another embodiment, a method for manufacturing a semiconductor is provided. The method includes forming a gate dielectric layer adjacent a semiconductor substrate. A gate electrode is formed covering at least a portion of the gate dielectric layer. First and second spacers are formed at least partially in contact with the gate electrode. The first and second spacers each comprise a material having a dielectric coefficient value equal to or greater than the dielectric coefficient value of silicon dioxide. First and second doped regions of the semiconductor substrate are formed proximate the first and second spacers, respectively. The method further includes removing the first and second spacers and forming third and fourth doped regions of the semiconductor substrate proximate the gate electrode and separated by a channel region. Third and fourth spacers are formed at least partially in contact with the gate electrode. The third and fourth spacers each comprise a material having a dielectric coefficient value less than the dielectric coefficient value of silicon dioxide.

Technical advantages of particular embodiments of the present invention include a transistor with a low-k spacer that reduces the capacitance between the gate electrode and the contacts. Accordingly, the overall capacitance of the transistor is in effect reduced and the transistor is more efficient and can switch at a higher speed.

Another technical advantage of particular embodiments of the present invention is the use of a cap layer, covering at least a portion of the low-k spacer. The cap layer provides a cleaner, more stable surface than the surface of the low-k spacer without a cap layer. Accordingly, the silicidation process which occurs prior to the formation of contacts on the transistor can be more easily controlled.

Other technical advantages will be readily apparent to one skilled in the art from the following figures, descriptions and claims. Moreover, while specific advantages have been enumerated above, various embodiments may include all, some or none of the enumerated advantages.

### BRIEF DESCRIPTION OF THE DRAWINGS

For a more complete understanding of the particular embodiments of the invention and their advantages, reference is now made to the following descriptions, taken in conjunction with the accompanying drawings, in which:

FIG. 1 is a cross-sectional diagram illustrating a transistor assembly, in accordance with a particular embodiment of the present invention;

FIG. 2 is a cross-sectional diagram illustrating a transistor assembly at one stage of a manufacturing process, in accordance with a particular embodiment of the present invention;

FIG. 3 is a cross-sectional diagram illustrating a transistor assembly at one stage of a manufacturing process, in accordance with an alternative embodiment of the present invention;

FIG. 4 is a cross-sectional diagram illustrating the transistor assembly of FIG. 3 at another stage of a manufacturing process, in accordance with an alternative embodiment of the present invention;

FIG. 5 is a cross-sectional diagram illustrating the transistor assembly of FIG. 4 at another stage of a manufacturing process, in accordance with an alternative embodiment of the present invention; and

FIG. 6 is a cross-sectional diagram illustrating the transistor assembly of FIG. 5 at another stage of a manufacturing process, in accordance with an alternative embodiment of the present invention.

### DETAILED DESCRIPTION OF THE INVENTION

FIG. 1 illustrates a transistor assembly 10 at one stage of a manufacturing process, in accordance with an embodiment of the present invention. Transistor assembly 10 includes low-k spacers 20 and 22 made of a material with a dielectric coefficient k value less than the k value of silicon dioxide (i.e., less than approximately 4.2). The low dielectric coefficient of low-k spacers 20 and 22 reduces the capacitance between gate electrode 14 and contacts 34 and 36, resulting in a reduction of the overall capacitance (gate-to-drain or gate-to-source capacitance) of transistor assembly 10. This reduction in effect increases the switching speed and efficiency of the transistor assembly.

Cap layers 28 and 30 at least partially cover low-k spacers 20 and 22, respectively, and change the surface properties of the resulting transistor assembly 10 above low-k spacers 20 and 22. Cap layers 28 and 30 comprise a material with a dielectric coefficient k value equal to or greater than the k value of silicon dioxide (i.e., equal to or greater than approximately 4.2), such as silicon nitride or silicon dioxide itself. Cap layers 28 and 30 have a less fragile surface than the surface of low-k spacers 20 and 22 without cap layers 28 and 30. Thus, cap layers 28 and 30 improve the silicidation process that occurs subsequent to the formation of low-k spacers 20 and 22 and add stability to transistor assembly 10.

As described in greater detail below, transistor assembly 10 also includes a semiconductor substrate 11 which comprises a wafer 13. Semiconductor substrate 11 also includes a gate dielectric layer 12 with a gate electrode 14 covering a portion of gate dielectric layer 12. Source extension 16 and drain extension 18 extend partially under gate dielectric layer 12 and are separated by a channel region 19. Transistor assembly 10 further includes source region 24 and drain region 26 that extend at least partially under low-k spacers 20 and 22, respectively. Transistor assembly 10 also includes silicide layer 32 and oxide layer 33. In the illustrated embodiment, contacts 34 and 36 are disposed upon silicide layer 32 of semiconductor substrate 11.

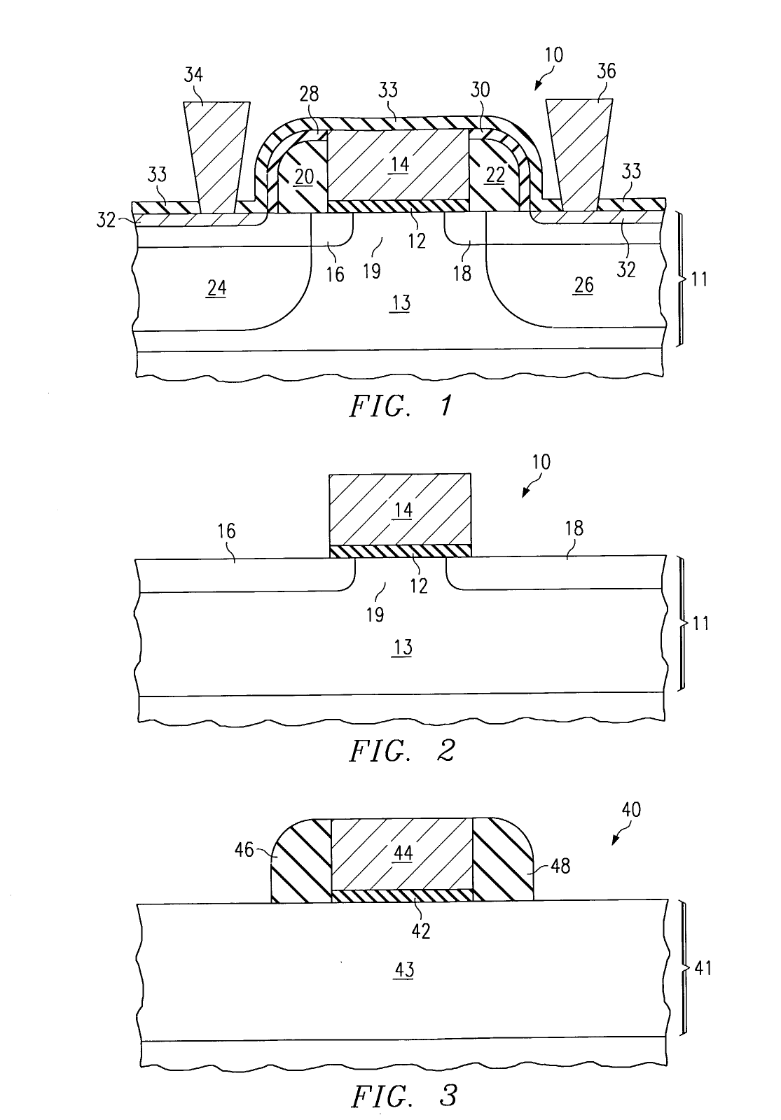

FIG. 2 illustrates a particular stage during the manufacturing process of transistor assembly 10 of FIG. 1. Semiconductor substrate 11 comprises wafer 13, which is formed from a single crystalline silicon material. Semiconductor substrate 11 may comprise other suitable materials or layers without departing from the scope of the present invention. For example, semiconductor substrate 11 may include an epitaxial layer, a recrystallized semiconductor material, a polycrystalline semiconductor material or any other suitable semiconductor material.

Transistor assembly 10 includes gate dielectric layer 12 and gate electrode 14. Gate dielectric layer 12 is disposed upon part of semiconductor substrate 11 and serves to insulate gate electrode 14 from semiconductor substrate 11. Gate dielectric layer 12 may be formed on part of semiconductor substrate 11 by any of a variety of techniques well known to those skilled in the art. Gate dielectric layer 12 may be composed of any appropriate type of insulating material, such as silicon dioxide or nitride oxide, and may have a thickness of approximately two nanometers.

Disposed on gate dielectric layer 12 is gate electrode 14. Gate electrode 14 may be formed on gate dielectric layer 12 by any of a variety of techniques well known to those skilled in the art, such as conventional photoresist and anisotropic etching processes. Gate electrode 14 may be composed of any appropriate conducting material, such as polycrystalline silicon, and may have a thickness of approximately one hundred twenty nanometers.

Next, source extension 16 and drain extension 18 are formed within semiconductor substrate 11. Source extension 16 and drain extension 18 extend at least partially under gate dielectric layer 12 and are separated by substantially undoped channel region 19 of semiconductor substrate 11. Source extension 16 and drain extension 18 facilitate the flow of electrons through semiconductor substrate 11.

Source extension 16 is formed by doping that particular region of semiconductor substrate 11. Doping semiconductor substrate 11 may be accomplished by ion implantation, diffusion or any other suitable process. Doping may cause source extension 16 to have an abundance of holes or an abundance of electrons. For example, if boron is used as the dopant, source extension 16 will have an abundance of holes, and, on the other hand, if arsenic is used as the dopant, source extension 16 will have an abundance of electrons. Accordingly, source extension 16 may be either N-type or P-type, and is typically of the opposite type from semiconductor substrate 11. Drain extension 18 may be formed in semiconductor substrate 11 by doping that particular region. Doping semiconductor substrate 11 may be accomplished by techniques similar to those used to form source extension 16 and typically results in drain extension 18 having an abundance of holes or electrons. Accordingly, drain extension 18 may be either N-type or P-type.

As discussed for the illustrated embodiment, source extension 16 and drain extension 18 may be interchangeable with each other. Thus, source extension 16 may behave as a drain extension, and drain extension 18 may behave as a source extension. In other embodiments, however, source extension 16 and drain extension 18 are not interchangeable.

Referring back to FIG. 1, transistor assembly 10 of FIG. 2 is illustrated at a further stage in the manufacturing process. After the formation of source extension 16 and drain extension 18, low-k spacers 20 and 22 are formed at least partially in contact with gate electrode 14. Low-k spacers 20 and 22 may be formed by any of a variety of techniques well known to those skilled in the art. In the illustrated embodiment, low-k spacers 20 and 22 are formed by depositing a material upon semiconductor substrate 11 and anisotropically etching away a portion of the material, leaving low-k spacers 20 and 22. Low-k spacers 20 and 22 serve as implant blocks for the subsequent formation of source region 24 and drain region 26. Low-k spacers 20 and 22 also prevent the shorting out of various components of transistor assembly 10, such as gate electrode 14, source region 24 and drain region 26, during the subsequent silicidation process. As stated above, low-k spacers 20 and 22 comprise a material with a dielectric coefficient k value less than the k value of silicon dioxide (i.e., less than approximately 4.2), such as HSQ, FSG or parylene. The low dielectric coefficient k value of low-k spacers 20 and 22 reduces the capacitance between gate electrode 14 and subsequently formed contacts 34 and 36. Since the capacitance between gate electrode 14 and contacts 34 and 36 is approximately ten to fifteen percent of the overall capacitance (gate-to-drain or gate-to-source capacitance) of transistor assembly 10, this reduction results in a reduction of the overall capacitance of transistor assembly 10. This reduction in effect increases the switching speed and efficiency of transistor assembly 10. The material of which low-k spacers 20 and 22 are comprised should also be dense enough so that low-k spacers 20 and 22 may adequately serve as implant blockers during the subsequent formation of source region 24 and drain region 26.

Source region 24 and drain region 26 are then formed at least partially under low-k spacers 20 and 22, respectively, to create low resistance regions that facilitate the flow of electrons through semiconductor substrate 11. The formation of source region 24 and drain region 26 is substantially similar to the formation of source extension 16 and drain extension 18; however, when forming source region 24 and drain region 26 the dopant penetrates further into semiconductor substrate 11. As with source extension 16 and drain extension 18, in the illustrated embodiment source region 24 and drain region 26 may be interchangeable with each other. Thus, source region 24 may behave as a drain region, and drain region 26 may behave as a source region. In other embodiments, however, source region 24 and drain region 26 are not interchangeable.

Cap layers 28 and 30 may be disposed upon low-k spacers 20 and 22, respectively, and, as stated above, change the surface properties of the resulting transistor assembly 10 above low-k spacers 20 and 22. Cap layers 28 and 30 comprise a material with a dielectric coefficient equal to or greater than that of silicon dioxide (i.e., equal to or greater than approximately 4.2), such as silicon nitride or silicon dioxide itself. Cap layers 28 and 30 have a surface less fragile than that of low-k spacers 20 and 22 and therefore provide a more stable surface which allows the silicidation process that occurs subsequent to the forming of low-k spacers 20 and 22 to be more controlled.

A material is then deposited that reacts with the material of semiconductor substrate 11 to form silicide layer 32. In general, the material used to form silicide layer 32 may be any material that reacts with the material of semiconductor substrate 11 to form a stable, low resistance layer. In general, metals such as platinum, tungsten, titanium, cobalt or nickel are good candidates for reacting with semiconductor substrate 11 to form silicide. The material used to form the silicided layer 32 may be applied by any of the variety of techniques well known to those skilled in the art. After applying such material and allowing it to react with the material of semiconductor substrate 11 to form silicide layer 11, the unreacted material may be removed by applying acid or by any other suitable manner.

Transistor assembly 10 also includes oxide layer 33 which may be formed to act as support for contacts 34 and 36 to be subsequently added. Oxide layer 33 may be formed by any of a variety of techniques well known to those skilled in the art and may be composed of any suitable material, such as nitride oxide.

Transistor assembly 10 additionally includes contacts 34 and 36. Contact 34 facilitates providing electrical current to source region 24 and source extension 16 of transistor assembly 10. Contact 36, in turn, facilitates extracting electrical current from drain region 26 and drain extension 18. Accordingly, contacts 34 and 36 may be composed of any acceptable type of electrically conductive material, such as, for example, titanium, aluminum or copper. Contacts 34 and 36 may be formed by any of a variety of techniques well known to those skilled in the art. In the illustrated embodiment, contacts 34 and 36 are formed by anisotropically etching oxide layer 32 where contacts 34 and 36 are to be placed. The material used for contacts 34 and 36 may then be deposited to form the contacts.

Although a particular configuration has been illustrated for transistor assembly 10 with respect to FIGS. 1 and 2, transistor assembly 10 may have a variety of other configurations in various embodiments. For example, source region 24 and drain region 26 do not have to be silicided, eliminating silicided layer 33. As another example, source region 24 and drain region 26 may have a variety of shapes. Moreover, gate electrode 14 and low-k spacers 20 and 22 may have a variety of shapes as well. As a further example, certain embodiments do not require oxide layer 33. A variety of other configurations will be readily suggested by those skilled in the art.

FIGS. 3 through 6 illustrate the manufacturing process of an alternative embodiment of the invention, in which removable high-k spacers are used and source and drain regions are formed prior to the formation of source and drain extensions. Accordingly, the material used for the low-k spacers of this embodiment does not necessarily have to be dense enough to serve as an implant block for the formation of source and drain regions. FIG. 3 shows a transistor assembly 40 at one stage of the manufacturing process, having semiconductor substrate 41 which comprises wafer 43. In FIG. 3, gate dielectric layer 42 is disposed upon semiconductor substrate 41, and gate electrode 44 is disposed upon gate dielectric layer 42. High-k spacers 46 and 48 are formed at least partially in contact with gate electrode 44 by any of a variety of techniques well known to those skilled in the art. High-k spacers 46 and 48 are comprised of a material with a dielectric coefficient k value greater than or equal to the k value of silicon dioxide (i.e., greater than or equal to approximately 4.2). In accordance with particular embodiments, such material should also be dense enough so that high-k spacers 46 and 48 may adequately serve as implant blocks for the subsequent formation of source region 50 and drain region 52. The use of high-k spacers 46 and 48 allows a manufacturer of transistor assembly 40 to choose from any of a number of materials dense enough to serve as implant blocks during the formation of source region 50 and drain region 52, since any materials with a dielectric coefficient k value above approximately 4.2 should have such a density.

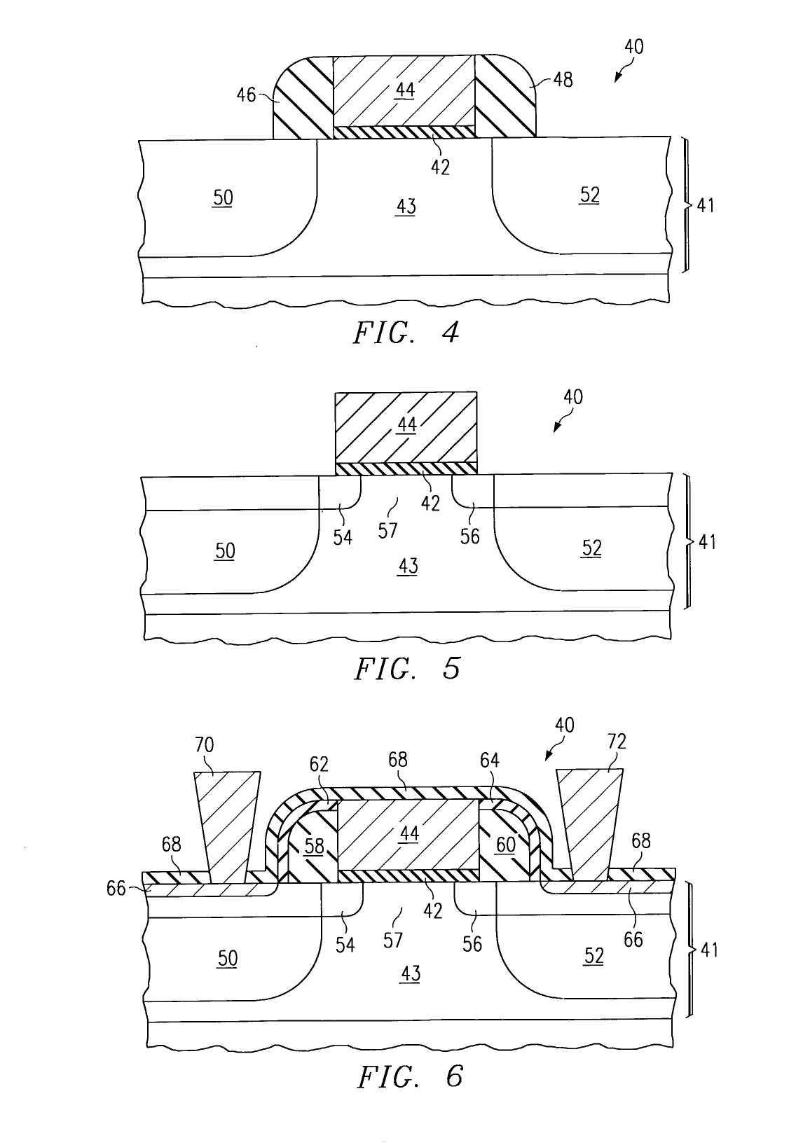

As illustrated in FIG. 4, following the formation of high-k spacers 46 and 48, source region 50 and drain region 52 are formed by a doping process which may be substantially similar to the process described earlier in relation to the formation of source region 24 and drain region 26 of transistor assembly 10. Like source region 24 and drain region 26, source region 50 and drain region 52 may be interchangeable in particular embodiments. Next, high-k spacers 46 and 48 are removed by any of a variety of techniques well known to those skilled in the art, such as selective etching.

As illustrated in FIG. 5, source extension 54 and drain extension 56, which extend at least partially under gate dielectric layer 42 and are separated by substantially undoped channel region 57, are then formed by a doping process which may be substantially similar to the process described earlier in relation to the formation of source extension 16 and drain extension 18 of transistor assembly 10. When forming source extension 54 and drain extension 56, the dopant does not penetrate as far into semiconductor substrate 41 as when forming source region 50 and drain region 52. Like source extension 16 and drain extension 18 of transistor assembly 10, source extension 54 and drain extension 56 may also be interchangeable in particular embodiments.

As illustrated in FIG. 6, low-k spacers 58 and 60 are then formed at least partially in contact with gate electrode 44. The use of a low-k material again reduces the capacitance between the gate electrode 44 and subsequently formed contacts 70 and 72. In this embodiment, the material of which low-k spacers 58 and 60 are comprised does not necessarily have to be dense enough to serve as an implant block for the formation of source region 50 and drain region 52, since source region 50 and drain region 52 have already been formed.

Cap layers 62 and 64 may then be formed upon low-k spacers 58 and 60, respectively, to provide a more stable surface for subsequent silicidation. Silicide layer 66 is then formed in semiconductor substrate 41. Oxide layer 68 is deposited and anisotropically etched away at locations where contacts 70 and 72 are to be placed. Contacts 70 and 72 are then deposited at the locations where oxide layer 68 was previously etched.

Although a particular configuration has been illustrated for transistor assembly 40 with respect to FIGS. 3 through 6, other embodiments of the present invention may have other configurations. For example, in particular embodiments transistor assembly 40 may not have to be silicided, eliminating silicide layer 66. Furthermore, gate electrode 44, high-k spacers 46 and 48 and low-k spacers 58 and 60 may have a variety of shapes. A variety of other configurations will be readily suggested by those skilled in the art.

Although the present invention has been described in detail, various changes and modifications may be suggested to one skilled in the art. It is intended that the present invention encompass such changes and modifications as falling within the scope of the appended claims.

What is claimed is:

1. A method for manufacturing a transistor of a semiconductor device, comprising:
forming a gate dielectric layer adjacent a semiconductor substrate;
forming a gate electrode covering at least a portion of the gate dielectric layer;
forming first and second doped regions of the semiconductor substrate proximate the gate electrode, the first and second doped regions separated by a channel region;
forming first and second spacers at least partially in contact with the gate electrode, the first and second spacers each comprising a material having a dielectric coefficient value less than the dielectric coefficient value of silicon dioxide; and
forming third and fourth doped regions of the semiconductor substrate proximate the first and second spacers, respectively.

2. The method of claim 1, further comprising:
forming first and second cap layers at least partially in contact with first and second spacers, respectively; and
wherein first and second cap layers each comprise a material having a dielectric coefficient value equal to or greater than the dielectric coefficient value of silicon dioxide.

3. The method of claim 2, further comprising forming a silicide layer of the semiconductor substrate proximate the first and second spacers.

4. The method of claim 1, further comprising forming an oxide layer of the semiconductor substrate proximate the first and second spacers.

5. The method of claim 1, further comprising forming first and second contacts proximate first and second spacers, respectively.

6. The method of claim 1, wherein the dielectric coefficient value of the material is less than approximately 4.2.

7. The method of claim 1, wherein the first and second spacers comprise parylene.

8. The method of claim 2, wherein the first and second cap layers comprise silicon nitride.

9. A method for manufacturing a transistor of a semiconductor device, comprising:
forming a gate dielectric layer adjacent a semiconductor substrate;
forming a gate electrode covering at least a portion of the gate dielectric layer;
forming first and second spacers at least partially in contact with the gate electrode, the first and second spacers each comprising a material having a dielectric coefficient value equal to or greater than the dielectric coefficient value of silicon dioxide;
forming first and second doped regions of the semiconductor substrate proximate the first and second spacers, respectively;
removing the first and second spacers;
forming third and fourth doped regions of the semiconductor substrate proximate the gate electrode, the third and fourth doped regions separated by a channel region; and
forming third and fourth spacers at least partially in contact with the gate electrode, the third and fourth spacers each comprising a material having a dielectric coefficient value less than the dielectric coefficient value of silicon dioxide.

10. The method of claim 9, further comprising:
forming first and second cap layers at least partially in contact with third and fourth spacers, respectively; and
wherein first and second cap layers each comprise a material having a dielectric coefficient value equal to or greater than the dielectric coefficient value of silicon dioxide.

11. The method of claim 10, further comprising forming a silicide layer of the semiconductor substrate proximate the third and fourth spacers.

12. The method of claim 9, further comprising forming an oxide layer of the semiconductor substrate proximate the third and fourth spacers.

13. The method of claim 9, further comprising forming first and second contacts proximate the third and fourth spacers.

14. The method of claim 9, wherein the dielectric coefficient value of the material is less than approximately 4.2.

15. The method of claim 9, wherein the third and fourth spacers comprise parylene.

16. The method of claim 9, wherein the first and second spacers comprise silicon nitride.

17. The method of claim 10, wherein the first and second cap layers comprise silicon nitride.

18. A transistor assembly, comprising:
a gate dielectric layer disposed upon a semiconductor substrate;
a gate electrode disposed at least partially upon the gate dielectric layer;
first and second doped regions of the semiconductor substrate proximate the gate electrode, the first and second doped regions separated by a channel region;
first and second spacers at least partially in contact with the gate electrode, the first and second spacers each comprising a material having a dielectric coefficient value less than the dielectric coefficient value of silicon dioxide;
third and fourth doped regions of the semiconductor substrate proximate the first and second spacers, respectively; and
first and second cap layers at least partially in contact with third and fourth spacers, respectively, the first and second cap layers each comprising a material having a dielectric coefficient value equal to or greater than the dielectric coefficient value of silicon dioxide.

19. The transistor assembly of claim 18, further comprising a silicide layer proximate the first and second spacers.

20. The transistor assembly of claim 18, further comprising an oxide layer proximate the first and second spacers.

21. The transistor assembly of claim 18, further comprising first and second contacts proximate first and second spacers, respectively.

22. The transistor assembly of claim 18, wherein the dielectric coefficient value of the material is less than approximately 4.2.

23. The transistor assembly of claim 18, wherein the first and second spacers comprise parylene.
